(19) United States
(12) Patent Application Publication
(10) Pub. No.: US 2024/0395969 A1
(43) Pub. Date: Nov. 28, 2024

(54) WIDE COLOR GAMUT LED PACKAGE STRUCTURE AND PRODUCTION METHOD THEREOF

(71) Applicant: Zhongshan Mulinsen Electronics Co., Ltd., Zhongshan (CN)

(72) Inventors: Baoqing PI, Zhongshan (CN); Hongguan WANG, Zhongshan (CN)

(73) Assignee: Zhongshan Mulinsen Electronics Co., Ltd., Zhongshan (CN)

(21) Appl. No.: 18/793,713

(22) Filed: Aug. 2, 2024

(30) Foreign Application Priority Data
May 30, 2024 (CN) 202410691286.6

(51) Int. Cl. H01L 33/08; H01L 33/00; H01L 33/06; H01L 33/32; H01L 33/48; H01L 33/50; H01L 33/56; H01L 33/62

(52) U.S. Cl. CPC H01L 33/08; H01L 33/0016; H01L 33/007; H01L 33/0095; H01L 33/06; H01L 33/32; H01L 33/483; H01L 33/50; H01L 33/56; H01L 33/62; H01L 2933/0041; H01L 2933/005; H01L 2933/0066

(57) ABSTRACT

The present disclosure provides a wide color gamut LED package structure and production method thereof, comprising a bracket, wherein an LED chip is mounted on a top surface of the bracket. A packaging mechanism is sleeved on the LED chip and includes a packaging glue, and the packaging glue is mixed with a red phosphor, The LED chip includes a multiple quantum well layer for generating light of different wavelengths. By integrating blue light and green light multiple quantum well layers in the LED chip, and combining with external red phosphor, when an LED lamp bead is electrified and emits light, the NTSC color gamut of spectrum composed of the blue light and green light of the chip, and the red phosphor is higher than that of the blue light excitation phosphor. By directly generating multi-color lights on a single chip, the chips used are reduced, thereby reducing costs.

### CROSS-REFERENCE TO RELATED APPLICATIONS

The application claims priority to Chinese patent application No. 202410691286.6, filed on May 30, 2024, the entire contents of which are incorporated herein by reference.

### TECHNICAL FIELD

The present disclosure relates to the technical field of LED (Light Emitting Diode), and in particular to a wide color gamut LED package structure and a production method thereof.

### BACKGROUND

An LED (Light Emitting Diode) is a solid-state semiconductor device and can convert an electrical energy into a light energy, which has the advantages of low power consumption, good focusing effect, fast response speed, strong controllability, high impact resistance, long service life, and environmental protection. The LED is gradually replacing traditional light sources and becoming the fourth-generation light sources. For LED package devices, different package structures will have a relatively large impact on the LED, such as affecting life, light-emitting angle, color gamut and so on.

In order to achieve wide color gamut lamp beads, many schemes use chips with wide color gamut phosphors. If blue light chips are matched with phosphors, an NTSC color gamut can only be about 95%, and the life is relatively short. If pure chips are used, the cost of the lamp beads will be very expensive.

The purpose of the present disclosure is to solve the problems of low color gamut and high price for the traditional LED lamp beads.

### SUMMARY

In order to solve the problems of relatively narrow color gamut and high price of the traditional LED lamp beads, the present disclosure provides the following technical solutions:

A wide color gamut LED package structure and production method thereof, comprises a bracket, wherein a function of the bracket is to provide physical support and electrical connection for components mounted on the bracket. An LED chip is mounted on a top surface of the bracket, a package mechanism is sleeved and arranged on the LED chip and includes a packaging glue, the packaging glue is mixed with a phosphor, and the phosphor are red.

The LED chip includes a multiple quantum well layer, and the multiple quantum well layer is used for generating light of different wavelengths. The multiple quantum well layer includes several blue light multiple quantum well layers and several green light multiple quantum well layers.

The wide color gamut LED package structure and production method thereof as described above, the blue light multiple quantum well layer and the green light multiple quantum well layer are both composed of an InGaN (indium gallium nitride) barrier layer and an InGaN well layer. The InGaN barrier layer of the green light multiple quantum well layer has a thickness of 5-25 nm with, an In content of 20%-85% and an emission wavelength of 515-550 nm. The InGaN well layer of the green light multiple quantum well layer has a thickness of 1-7 nm and with an In content of 1%-25%. The InGaN barrier layer of the blue light multiple quantum well layer has a thickness of 5-25 nm, with an In content of 10%-40% and an emission wavelength of 440-470 nm. The InGaN well layer of the blue light multiple quantum well layer has a thickness of 1-7 nm with an In content of 1%-25%.

The wide color gamut LED package structure and production method thereof as described above, a P-type GaN layer (hole-type gallium nitride layer) is arranged above the multiple quantum well layer, an N-type GaN layer (electron-type gallium nitride layer) is arranged below the multiple quantum well layer, the N-type GaN layer is used to provide electrons, the P-type GaN layer is used to provide holes, and the P-type GaN layer and the N-type GaN layer form a P-N junction together.

The wide color gamut LED package structure and production method thereof as described above, an undoped GaN layer is arranged below the N-type GaN layer, the LED chip includes a substrate, and a GaN buffer layer is arranged between the undoped GaN layer and the substrate.

The wide color gamut LED package structure and production method thereof as described above, the packaging mechanism includes a bracket cup that is made of a transparent or opaque material, the bracket cup is fixedly connected to the bracket, and is sleeved outside the packaging glue.

The wide color gamut LED package structure and production method thereof as described above, positive and negative electrodes of the LED chip are both welded with bonding wires, an end of the bonding wire is fixedly connected to the bracket, and the bracket is electrically connected to the LED chip through the bonding wire.

The wide color gamut LED package structure and production method thereof as described above, a side of the LED chip in contact with the bracket is coated with a die bonding glue, and the LED chip is fixedly connected to the bracket through the die bonding glue.

The wide color gamut LED package structure and production method thereof as described above, several blue light multiple quantum well layers and several green light multiple quantum well layers are alternately stacked.

A production method for the wide color gamut LED package structure comprises the following steps:
Step 1: growing an epitaxial layer, wherein a metal-organic chemical vapor deposition (MOCVD) is used to grow the epitaxial layer for an LED chip;
Step 2: fabricating the LED chip, wherein electrodes, current expansion layers, current blocking layers, protective layers, reflective layers, etc. are made on the chip, and finally single LED chips are obtained after cutting;
Step 3: die bonding, wherein the LED chip is fixed on a bracket;
Step 4: bonding wire, wherein the bracket is electrically connected to the chip through a bonding wire;
Step 5: setting a fluorescent glue, wherein the fluorescent glue is set on a side of a functional area of the bracket by means of dispensing or spraying. Preferably, the phosphor in the fluorescent glue is a red fluoride phosphor; and
Step 6: testing and packaging.

The production method for wide color gamut LED package structure, wherein the step 1 further comprises the following steps:
adjusting a reaction chamber temperature to the range of 650-950° C. to lay a foundation for a high-quality growth of InGaN materials; when the green light multiple quantum well layer is growing, a thickness of a green light multiple quantum well barrier layer is set to be 5-25 nm, an In content is in the range of 20%-85%, a thickness of a well layer is set to be 1-7 nm, and a target band is locked at 515-550 nm; when the blue light multiple quantum well is growing, the barrier layer thickness of the blue light multiple quantum well barrier layer is set to be 5-25 nm, with an In content is in the range of 10%-40%, a thickness of a well layer is set to be 1-7 nm, and a target band is locked at 440-470 nm.

The embodiments of the present disclosure have the following beneficial effects.
1. In the present disclosure, by integrating the blue light and green light multiple quantum well layers in the LED chip and combining with the external red phosphor, when the LED lamp bead is electrified and emits light, the NTSC color gamut of the spectrum composed of the blue light of the chip, the green light of the chip and the red phosphor is higher than that of the blue light excitation phosphor. Besides, multi-color lights are directly generated on the single chip, which has reduced the dependence on the pure chip scheme, and the chips used are less than those used in the pure chip scheme, thereby reducing the costs.
2. The undoped GaN layer and the GaN buffer layer are used in the present disclosure, which can effectively alleviate the lattice mismatch among different materials and reduce the dislocation density, thereby enhancing the bonding quality and long-term reliability of the LED device.

In summary, the present disclosure solves the problems of low color gamut and high price for the traditional LED lamp beads.

### BRIEF DESCRIPTION OF DRAWINGS

In order to more clearly illustrate the technical solutions in embodiments of the present disclosure, the drawings required to be used in the description of the embodiments will be briefly introduced below. Obviously, the drawings described below are only some embodiments of the present disclosure. For ordinary technicians in this field, other drawings are obtained based on these drawings without paying any creative work.

FIG. 1 is a structural schematic diagram of a wide color gamut LED package structure of the present disclosure when a face up chip is installed.

FIG. 2 is a structural schematic diagram of an LED chip of a wide color gamut LED package structure and production method thereof according to the present disclosure.

FIG. 3 is a structural schematic diagram of a multiple quantum well layer of the wide color gamut LED package structure and production method thereof according to the present disclosure.

FIG. 4 is a structural schematic diagram of the wide color gamut LED package structure of the present disclosure when a flip chip is installed.

FIG. 5 is a structural schematic diagram of a blue light multiple quantum well layers or green light multiple quantum well layers of the wide color gamut LED package structure and production method thereof according to the present disclosure.

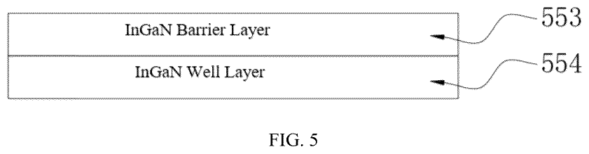

### DETAILED DESCRIPTION OF THE EMBODIMENTS

The following will be combined with the drawings in the embodiments of the present disclosure to clearly and completely describe the technical solutions in the embodiments of the present disclosure. Obviously, the described embodiments are only part of the embodiments of the present disclosure, not all of the embodiments. Based on the embodiments in the present disclosure, all other embodiments obtained by ordinary technicians in this field without creative work are within the scope of protection of the present disclosure.

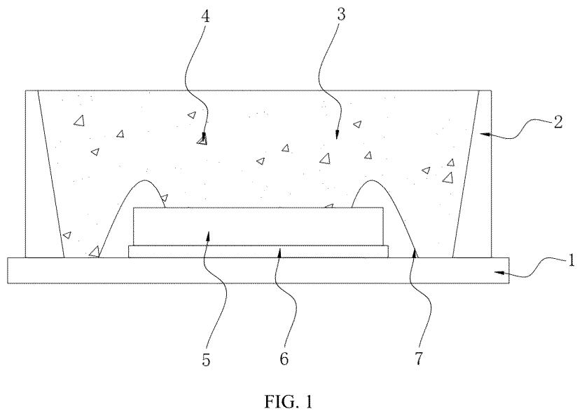

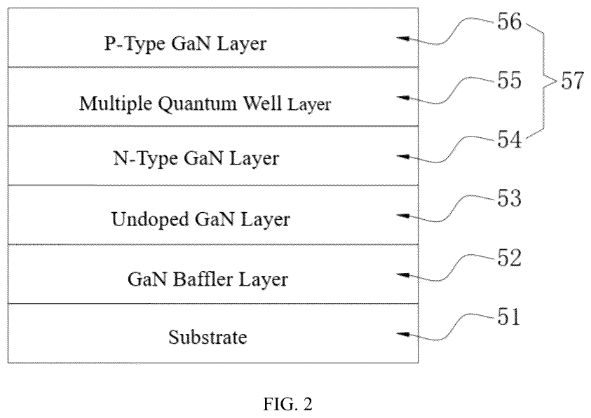

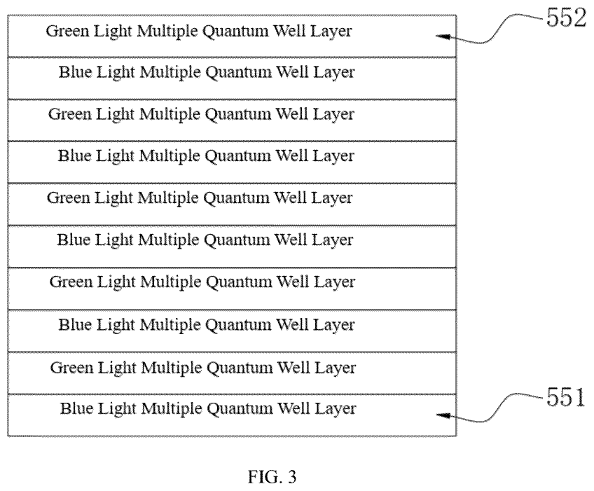

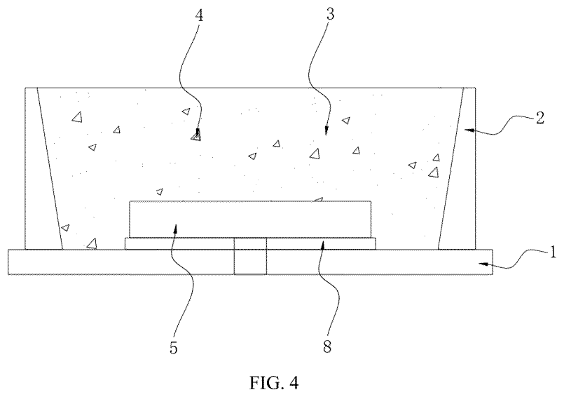

As shown in FIGS. 1 to 4, the present disclosure proposes a wide color gamut LED package structure and a production method thereof, comprising a bracket 1, wherein a function of the bracket 1 is to provide physical support and electrical connection for components mounted on the bracket 1, a top surface of the bracket 1 is provided with an LED chip 5, and the LED chip 5 is made of one of a face up chip, a vertical chip and a flip chip. A packaging mechanism is sleeved outside the LED chip 5 and includes a packaging glue 3, the material of the packaging glue 3 is one of PCT (polycyclohexane terephthalate) injection molding material, PPA (polyphthalamide) injection molding material, epoxy resin and silica gel, and the packaging glue 3 is mixed with phosphor 4.

The LED chip 5 includes a multiple quantum well layer 55 used for generating lights of different wavelengths. The multiple quantum well layer 55 includes several blue light multiple quantum well layers 551 and several green light multiple quantum well layers 551.

As a light-emitting element, the LED chip 5 includes the multiple quantum well layer 55. The multiple quantum well layer 55 is composed of several very thin semiconductor layers, which can change the recombination process of electrons and holes through the quantum confinement effect, so as to control and release the energy of the photons, that is, the wavelength of light. The blue light multiple quantum well layer 551 and the green light multiple quantum well layer 551 are responsible for generating blue light and green light, respectively. By adjusting the structures and materials of these multiple quantum wells, light of specific wavelength band can be effectively generated, laying the foundation for wide color gamut display.

The phosphor 4 is mixed with the packaging glue 3 to form a fluorescent glue, the weight of the phosphor particles is 0%-90% of the weight of the fluorescent glue. The packaging glue 3 is one of silica gel, epoxy resin or modified epoxy silicone resin, and the phosphor particles contain one or more phosphors 4, and the material of the phosphor 4 can be one or more of exciting light materials such as nitrogen oxides, aluminates, silicates, nitrides, sulfides, fluorides, etc. The material of the phosphor 4 is preferably fluoride.

Optionally, in some embodiments, when an LED chip 5 is a face up chip or a flip chip, a material of a substrate 51 is sapphire. The sapphire substrate has extremely high chemical stability and thermal stability, which is suitable for the high temperature environment during the LED growth.

Optionally, in some embodiments, when an LED chip 5 is a vertical chip, a material of a substrate 51 is silicon or silicon carbide. The silicon is the most commonly used material in the semiconductor industry, with large output and low cost, and the thermal conductivity of the silicon is better than that of the sapphire, which helps to improve the heat dissipation performance of the LED.

Optionally, in some embodiments, a material of a substrate 51 is gallium nitride. The gallium nitride substrate has a high lattice matching degree with the gallium nitride epitaxial layer, which can grow high-quality epitaxial films, thereby greatly reducing the dislocation density and improving the device performance.

Further, as a preferred embodiment of the present disclosure but not a limitation, a color of a phosphor 4 is red. Through the conversion effect of the red phosphor, the LED light source can obtain red light components in addition to the directly emitted blue light and green light, which significantly broadens the color gamut coverage of the light source. Specifically, in a display technology, a combination of red, green and blue (RGB three primary colors) is a basis for building a wide range of colors, so the addition of the red phosphor can generate more saturated red and rich and delicate colors.

Optionally, in some embodiments, a color of a phosphor 4 is yellow. The yellow phosphor can interact with the directly emitted blue light and green light to supplement the yellow part of the light source, and can also indirectly synthesize white light with the blue light or richer intermediate colors with the green and blue lights, thereby improving the saturation and naturalness of the overall color.

Further, as a preferred embodiment of the present disclosure but not a limitation, the blue light multiple quantum well layer 551 and the green light multiple quantum well layer 552 are both composed of an InGaN barrier layer 553 and an InGaN well layer 554. The InGaN barrier layer 553 of the green light multiple quantum well layer 552 has a thickness of 5-25 nm, with an In content of 20%-85%, and an emission wavelength of 515-550 nm, which can cover the green light region, thereby enhancing the green expression of the LED chip and broadening the overall color gamut. The InGaN well layer 554 of the green light multiple quantum well layer 552 has a thickness of 1-7 nm, and an In content of 1%-25%, aiming at optimizing the emission efficiency of the green light and ensuring a good electronic structure matching between the barrier layers, thus to promote effective transitions between energy levels. The InGaN barrier layer 553 of the blue light multiple quantum well layer 551 has a thickness of 5-25 nm, with an In content of 10%-40%, and an emission wavelength of 440-470 nm. The blue light is the basic light source of the LED, which provides efficient energy for subsequent phosphor excitation. The InGaN well layer 554 of the blue light multiple quantum well layer 551 has a thickness of 1-7 nm, and an In content of 1%-25%, which corresponds to the well layer design in the green light multiple quantum well layer 552, thus to optimize the blue light emission efficiency and the overall performance of the device.

Further, as a preferred embodiment of the present disclosure but not a limitation, a P-type GaN layer 56 is provided above the multiple quantum well layer 55, a thickness of the P-type GaN layer 56 is about 50-250 nm, and a doping concentration of Mg is greater than 10¹⁸ atoms/cm³. An N-type GaN layer 54 is provided below the multiple quantum well layer 55, a thickness of the N-type GaN layer 54 is about 0.5-5 μm, and a doping concentration of Si is greater than 10¹⁸ atoms/cm³. The N-type GaN layer 54 is used to provide electrons, and the P-type GaN layer 56 is used to provide holes, and the P-type GaN layer 56 and the N-type GaN layer 54 form a P-N junction 57 together. The LED chip 5 is a traditional LED chip with a single P-N junction 57, or a high-voltage LED chip with multiple P-N junctions 57 in series and parallel at the chip level, or multiple independent P-N junction 57 structures integrated on the same substrate. The N-type GaN layer 54 introduces excess electrons by doping with Si element, and becomes the source of the electrons. The P-type GaN layer 56 introduces a state of lack of electrons by doping with Mg, namely holes, and becomes a positive charge carrier. When the LED chip 5 is connected to a power supply, the electrons and holes are injected into the multiple quantum well regions respectively from the P-type GaN layer and the N-type GaN layer under the action of the electric field. When the electrons and holes are combined in the multiple quantum well layer 55, the electrons jump from a conduction band to a valence band to fill the holes, and the excess energy is released in the form of photons simultaneity.

Furthermore, as a preferred embodiment of the present disclosure but not a limitation, an undoped GaN layer 53 is provided below the N-type GaN layer 54, and a thickness of the undoped GaN layer 53 is 0.5-3 μm. As a lattice matching layer, the undoped GaN layer 53 can effectively alleviate the mismatch stress caused by the difference in lattice constants between GaN and different materials such as sapphire or silicon substrates, and reduce the dislocation density, thus to improve the overall bonding quality and reliability of the device. The undoped GaN layer 53 serves as a barrier layer between the N-type GaN layer 54 and the substrate 51, which helps to prevent or reduce the direct penetrations of the electrons into the substrate 51, thereby optimizing the electrical performance of the device. The LED chip 5 includes the substrate 51, and the material of the substrate 51 is one of sapphire, silicon or gallium nitride. A GaN buffer layer 52 is provided between the undoped GaN layer 53 and the substrate 51, and a thickness of the GaN buffer layer 52 is 20-40 nm. The main function of the GaN buffer layer 52 is to bridge the lattice difference between the substrate 51 and the N-type GaN layer 54. and the dislocation caused by the lattice mismatch is effectively reduced through progressive growth, thereby improving the bonding quality of the subsequent epitaxial layer. In addition, it can also help to improve the material adhesion and provide a flatter and more uniform growth platform for the top structure.

Further, as a preferred embodiment of the present disclosure but not a limitation, the total number of layers of the multiple quantum well layer 55 is at least two layers, including a blue light multiple quantum well layer 551 and a green light multiple quantum well layer 552. Through at least one blue light multiple quantum well layer 551 and one green light multiple quantum well layer 552, the foundation of a wide color gamut LED is laid. The blue light is the main excitation source of LED light, while the green light broadens the color gamut and improves color saturation. The combination of the two can initially achieve good coverage of the blue and green regions, laying the foundation for achieving wide color gamut light luminescence.

Optionally, in some embodiments, the total number of layers of the multiple quantum well layer 55 is 5 to 10 layers. By adjusting the total number of layers of the multiple quantum well layer 55, the light output intensity and spectral characteristics of the LED can be regulated. The range of 5 to 10 layers can ensure sufficient quantum wells, so as to improve the luminous efficiency while avoiding the increase of complexity and the possible decrease of efficiency caused by excessive stacking.

Further, as a preferred embodiment of the present disclosure but not a limitation, the packaging mechanism includes a bracket cup 2, and the bracket cup 2 is made of a transparent material. The bracket cup 2 is fixedly connected to the bracket 1, and is sleeved outside the packaging glue 3. The bracket cup 2 provides a physical support for the packaging glue 3, and is made of the transparent material. The bracket cup 2 can be used as an optical channel, so that the light emitted by the LED chip and the light converted by the phosphor can be transmitted smoothly without affecting the light efficiency, thereby optimizing the light distribution.

Optionally, in some embodiments, the bracket cup 2 is made of an opaque material, and the opaque material can be used as a light barrier to shield unwanted stray light, and guide the light to emit in a specific direction, thus to improve the directivity of the light source.

Further, as a preferred embodiment of the present disclosure but not a limitation, positive and negative electrodes of the LED chip 5 are both welded with bonding wires 7, and the bonding wire 7 is made of one of gold wire, silver wire, copper wire, aluminum wire or alloy wire. One end of the bonding wires 7 is fixedly connected to the bracket 1, and the bracket 1 is electrically connected to the LED chip 5 through the bonding wire 7. The bonding wire 7 enables the current to be transmitted from the external circuit to the LED chip 5 via the bracket 1, activating the PN junction and generating light.

Further, as a preferred embodiment of the present disclosure but not a limitation, a side of the LED chip 5 in contact with the bracket 1 is coated with a die bonding glue 6, and the LED chip 5 is fixedly connected to the bracket 1 through the die bonding glue 6.

Optionally, in some embodiments, when the LED chip 5 is a face up chip, the die bonding glue 6 is made of one of silica gel, epoxy resin or silica gel doped with alumina; when the LED chip 5 is a vertical chip, the die bonding glue 6 is made of one of conductive silver glue or solder paste; and when the LED chip 5 is a flip chip, the die bonding glue 6 is made of one of gold tin, solder paste, and silver glue.

Further, as a preferred embodiment of the present disclosure but not a limitation, several blue light multiple quantum well layers 551 and several green light multiple quantum well layers 552 are alternately stacked. By alternately arranging the blue light multiple quantum well layers 551 and the green light multiple quantum well layers 552 in the package structure, not only the efficient emission of each band can be obtained, but also the fine tuning and expansion of the spectrum can be achieved through the superposition effect of the two. The alternative stacking of multiple quantum well layers with different wavelengths helps to improve the absorption and conversion efficiency of light. The blue light layers are used for the basic high-intensity excitation, and the green light layers are used supplementing and adjusting the color temperature. Under the synergistic effect of the two, high brightness output is guaranteed, and the color distribution is more uniform and natural, reducing the color deviation.

Optionally, in some embodiments, several blue light multiple quantum well layers 551 and several green light multiple quantum well layers 552 are stacked in groups, that is, all the blue light multiple quantum well layers 551 are stacked first and then all the green light multiple quantum well layers 552 are stacked, or all the green light multiple quantum well layers 552 are stacked first and then all the blue light multiple quantum well layers 551 are stacked. Stacking in groups simplifies the manufacturing process steps, avoids the complex and precise control required in the alternating deposition process of the quantum well layers with different wavelengths, reduces the manufacturing difficulty and cost, and improves production efficiency. Due to the similar interface properties between similar quantum well layers, stacking is groups is beneficial to reduce interface defects and improve the internal consistency of the device, thereby improving the overall photoelectric conversion efficiency and reliability.

Optionally, in some embodiments, several blue light multiple quantum wells 551 and several green light multiple quantum wells 552 are randomly stacked. The random stacking may lead to a certain randomness of spectral output, which may be regarded as an advantage in certain specific applications, such as simulating the complex spectral changes of natural light, or creating more natural and irregular light and shadow effects in certain lighting applications.

A production method of high color gamut LED package structure comprises the following steps:
Step 1: growing an epitaxial layer, wherein a metal-organic chemical vapor deposition (MOCVD) is used to grow the epitaxial layer for an LED chip;
Step 2: fabricating the LED chip, wherein electrodes, current expansion layers, current blocking layers, protective layers, reflective layers, etc. are made for the chips, and finally single LED chips are obtained after cutting;
Step 3: die bonding, wherein the LED chip is fixed on a bracket;
Step 4: bonding wire, wherein the bracket is electrically connected to the chip through a bonding wire;
Step 5: setting a fluorescent glue, wherein the fluorescent glue is set on a side of a functional area of the bracket by means of dispensing or spraying. Preferably, the phosphor in the fluorescent glue is a red fluoride phosphor; and
Step 6: testing and packaging.

The Step 1 also includes the following steps:
S1: Pre-treating the substrate, wherein the reaction chamber is heated to 1000-1200° C. to bake the substrate so as to remove moisture and impurities on surfaces of the substrate, thus to improve the adhesion of the subsequent epitaxial layer, and the time is controlled within 5-20 mins so as to achieve the best cleaning effect.
S2: Adjusting the temperature of the reaction chamber to the range of 400 to 600° C., which is beneficial to the stable growth of the GaN materials and reduces the strain and defects during the growth process, wherein the MOCVD is used to grow a GaN buffer layer with a thickness of 20-40 nm for providing a smooth, uniform and low-defect substrate for the subsequent growth of the epitaxial layer.
S3: Adjusting the temperature of the reaction chamber to 1000-1200° C. to grow a undoped GaN layer 53 with a thickness of 0.5-3 μm as the basis for the subsequent doping layer, to further enhance the structural stability and electrical properties.
S4: Adjusting the temperature of the reaction chamber to 1000-1200° C. to grow an N-type doped GaN layer with a thickness of about 0.5 to 5 μm by introducing silicon (Si) as a dopant into the reaction gas, wherein the doping concentration of silicon is controlled to be higher than 1×10¹⁸ atoms/cm³ to ensure high conductivity.
S5: Adjusting the temperature of the reaction chamber to the range of 650-950° C. to lay a foundation for high-quality growth of the InGaN materials. When the green light multiple quantum well layer is growing, a thickness of a barrier layer of the green light multiple quantum well is set to be 5-25 nm, an In content is in the range of 20%-85%, a thickness of a well layer is 1-7 nm, and a target band is locked at 515-550 nm; when the blue light multiple quantum well layer is growing, a thickness of a barrier layer of the blue light multiple quantum well is set to be 5-25 nm, with an In content is in the range of 10%-40%, a thickness of a well layer is 1-7 nm, and a target band is locked at 440-470 nm.
S6: Adjusting the temperature of the reaction chamber to 900-1100° C. to grow a P-type GaN layer, wherein within this temperature range, a P-type GaN layer with a thickness of about 50-250 nm is grown by adding magnesium (Mg) as a doping element, and a doping concentration of the magnesium (Mg) is >1×10¹⁸/cm³ to ensure effective hole injection.
S7: Reducing the temperature below 800° C. for annealing process to release stress, thus to stabilize the bonding structure and enhance device performance and reliability.
S8: Completing the electrical connections and cutting into single chips ready for packaging and final testing.

As shown in FIGS. 1 to 3, the implementation method of Embodiment 1 is as follows.

The wide color gamut LED package structure and production method thereof comprises a bracket 1, and a function of the bracket 1 is to provide physical support and electrical connection for components mounted on the bracket 1, a top surface of the bracket 1 is provided with an LED chip 5, and the LED chip 5 is a face up chip. A material of a substrate 51 is sapphire. The sapphire substrate has extremely high chemical stability and thermal stability, which is suitable for the high temperature environment during the LED growth. A packaging mechanism is sleeved outside the LED chip 5, which includes a packaging glue 3, a material of the packaging glue 3 is one of PCT (polycyclohexane terephthalate) injection molding plastic, and the packaging glue 3 is mixed with a phosphor 4 to form a fluorescent glue. The weight of the phosphor particles is 0%-90% of the weight of the fluorescent glue, the packaging glue 3 is made of silica gel and the material of the phosphor 4 is preferably fluoride.

The LED chip 5 includes a multiple quantum well layer 55 used for generating light of different wavelengths. The multiple quantum well layer 55 includes several blue light multiple quantum well layers 551 and several green light multiple quantum well layers 551.

As a light-emitting element, the LED chip 5 includes the multiple quantum well layer 55. The multiple quantum well layer 55 is composed of several very thin semiconductor layers, which can change the recombination process of electrons and holes through the quantum confinement effect, so as to control and release the energy of the photons, that is, the wavelength of light. The blue light multiple quantum well layer 551 and the green light multiple quantum well layer 551 are responsible for generating blue light and green light, respectively. By adjusting the structures and materials of these multiple quantum wells, light of specific wavelength band can be effectively generated, laying the foundation for wide color gamut display.

The color of the phosphor 4 is red. Through the conversion effect of the red phosphor, the LED light source can obtain red light components in addition to the directly emitted blue light and green light, which significantly broadens the color gamut coverage of the light source. Specifically, in a display technology, a combination of red, green and blue (RGB three primary colors) is a basis for building a wide range of colors, so the addition of the red phosphor can generate more saturated red and rich and delicate colors.

The blue light multiple quantum well layer 551 and the green light multiple quantum well layer 552 are both composed of an InGaN barrier layer 553 and an InGaN well layer 554. The InGaN barrier layer 553 of the green light multiple quantum well layer 552 has a thickness of 5-25 nm, AN In content of 20%-85%, and an emission wavelength of 515-550 nm, which can cover the green light region, thereby enhancing the green expression of the LED chip and broadening the overall color gamut. The InGaN well layer 554 of the green light multiple quantum well layer 552 has a thickness of 1-7 nm, with an In content of 1%-25%, aiming at optimizing the emission efficiency of the green light and ensuring a good electronic structure matching between the barrier layers, thus to promote effective transitions between energy levels. The InGaN barrier layer 553 of the blue light multiple quantum well layer 551 has a thickness of 5-25 nm, an In content of 10%-40%, and an emission wavelength of 440-470 nm. The blue light is the basic light source of the LED which provides efficient energy for subsequent phosphor excitation. The InGaN well layer 554 of the blue light multiple quantum well layer 551 has a thickness of 1-7 nm, with an In content of 1%-25%, which corresponds to the well design in the green light multiple quantum well layer 552, thus to optimize the blue light emission efficiency and the overall performance of the device.

A P-type GaN layer 56 is provided above the multiple quantum well layer 55, a thickness of the P-type GaN layer 56 is about 50-250 nm, and a doping concentration of Mg is greater than 1018 atoms/cm3. An N-type GaN layer 54 is provided below the multiple quantum well layer 55, a thickness of the N-type GaN layer 54 is about 0.5-5 μm, and a doping concentration of Si is greater than 1018 atoms/cm3. The N-type GaN layer 54 is used to provide electrons, and the P-type GaN layer 56 is used to provide holes, and the P-type GaN layer 56 and the N-type GaN layer 54 form a P-N junction 57 together. The N-type GaN layer 54 introduces excess electrons by doping with Si element and becomes the source of the electrons. The P-type GaN layer 56 introduces a state of lack of electrons by doping with Mg, namely holes, and becomes a positive charge carrier. When the LED chip 5 is connected to a power supply, the electrons and holes are injected into the multiple quantum well regions respectively from the P-type GaN layer 56 and the N-type GaN layer 54 under the action of the electric field. When the electrons and holes are combined in the multiple quantum well layer 55, the electrons jump from a conduction band to a valence band to fill the holes, and the excess energy is released in the form of photons simultaneity.

An undoped GaN layer 53 is provided below the N-type GaN layer 54, and a thickness of the undoped GaN layer 53 is 0.5-3 μm. As a lattice matching layer, the undoped GaN layer 53 can effectively alleviate the mismatch stress caused by the difference in lattice constants between GaN and different materials, such as sapphire or silicon substrates, and reduce the dislocation density, and thus to improve the overall crystal quality and reliability of the device. The undoped GaN layer 53 serves as a barrier layer between the N-type GaN layer 54 and the substrate 51, which helps to prevent or reduce the direct penetrations of the electrons into the substrate 51, thereby optimizing the electrical performance of the device. The LED chip 5 includes a substrate 51, and the substrate 51 is made of sapphire, the sapphire substrate has extremely high chemical stability and thermal stability, which is suitable for high temperature environment during LED growth. A GaN buffer layer 52 is provided between the undoped GaN layer 53 and the substrate 51, and the GaN buffer layer 52 has a thickness of 20-40 nm. The main function of the GaN buffer layer 52 is to bridge the lattice difference between the substrate 51 and the N-type GaN layer 54, and the dislocation caused by the lattice mismatch is effectively reduced through progressive growth, thereby improving the crystal quality of the subsequent epitaxial layer. In addition, it can also help to improve the material adhesion and provide a flatter and more uniform growth platform for the top structure.

The total number of layers of the multiple quantum well layer 55 is at least two layers, including a blue light multiple quantum well layer 551 and a green light multiple quantum well layer 552. Though at least one blue light multiple quantum well layer 551 and one green light multiple quantum well layer 552, the foundation of a wide color gamut LED is laid. The blue light is the main excitation source of LED light, while the green light broadens the color gamut and improves color saturation. The combination of the two can initially achieve good coverage of the blue and green regions.

The packaging mechanism includes a bracket cup 2, and the bracket cup 2 is made of a transparent material. The bracket cup 2 is fixedly connected to the bracket 1, and is sleeved outside the packaging glue 3. The bracket cup 2 provides a physical support for the packaging glue 3, and is made of the transparent material. The bracket cup 2 can be used as an optical channel, so that the light emitted by the LED chip and the light converted by the phosphor can be transmitted smoothly, without affecting the light efficiency, thereby optimizing the light distribution.

Positive and negative electrodes of the LED chip 5 are both welded with bonding wires 7, and the bonding wire 7 is made of gold wire, which has superior conductivity, good corrosion resistance and stability in high temperature and humid environment. The use of gold wire can ensure long-term electrical connection reliability and reduce the risk of open circuit or short circuit, thereby improving the stability and service life of the entire LED device. One end of the bonding wire 7 is fixedly connected to the bracket 1, and the bracket 1 is electrically connected to the LED chip 5 through the bonding wire 7. The bonding wire 7 enables the current to be transmitted from the external circuit to the LED chip 5 via the bracket 1, activating the PN junction and generating light.

A side of the LED chip 5 in contact with the bracket 1 is coated with a die bonding glue 6, the LED chip 5 is fixedly connected to the bracket 1 through the die bonding glue 6, and the die bonding glue 6 is made of silver glue.

Several blue light multiple quantum well layers 551 and several green light multiple quantum well layers 552 are alternately stacked. By alternately arranging the blue and green light multiple quantum well layers in the package structure, not only the efficient emission of each band can be obtained, but also the fine tuning and expansion of the spectrum can be achieved through the superposition effect of the two. The alternative stacking of the multiple quantum well layers with different wavelengths helps to improve the absorption and conversion efficiency of light. The blue light layers are used for the basic high-intensity excitation, and the green light layers are used for supplementing and adjusting the color temperature. Under the synergistic effect of the two, high brightness output is guaranteed, and the color distribution is more uniform and natural, reducing the color deviation.

A production method of high color gamut LED package structure comprises the following steps:
Step 1: growing an epitaxial layer, wherein a metal-organic chemical vapor deposition (MOCVD) used to grow the epitaxial layer for an LED chip;
Step 2: fabricating the LED chip, wherein electrodes, current expansion layers, current blocking layers, protective layers, reflective layers, etc. are made to the chip, and finally single LED chips are obtained after cutting;
Step 3: die bonding, wherein the LED chip is fixed on a bracket;
Step 4: bonding wire, wherein the bracket is electrically connected to the chip through a bonding wire;
Step 5: setting a fluorescent glue, wherein the fluorescent glue is set on a side of a functional area of the bracket by means of dispensing or spraying. Preferably, the phosphor in the fluorescent glue is a red fluoride; and
Step 6: testing and packaging.

The Step 1 also includes the following steps:
S1: Pre-treating the substrate, wherein the reaction chamber is heated to 1000-1200° C. to bake the substrate, so as to remove moisture and impurities on surfaces of the substrate, thus to improve the adhesion of the subsequent epitaxial layer, and the time is controlled within 5-20 mins so as achieve the best cleaning effect.
S2: Adjusting the temperature of the reaction chamber to the range of 400 to 600° C., which is beneficial to the stable growth of the GaN materials, and reduces the strain and defects during the growth process, wherein the MOCVD is used to grow a GaN buffer layer with a thickness of 20-40 nm for providing a smooth, uniform and low-defect substrate for the subsequent growth of the epitaxial layer.
S3: Adjusting the temperature of the reaction chamber to 1000-1200° C. to grow a undoped GaN layer 53 with a thickness of 0.5-3 μm as the basis for the subsequent doping layer, to further enhance the structural stability and electrical properties.
S4: Adjusting the temperature of the reaction chamber to 1000-1200° C. to grow an N-type doped GaN layer with a thickness of about 0.5-5 μm by introducing silicon (Si) as a dopant into the reaction gas, wherein the doping concentration of silicon is controlled to be higher than 1×10¹⁸ atoms/cm³ to ensure high conductivity.
S5: Adjusting the temperature of the reaction chamber to the range of 650-950° C. to lay a foundation for high-quality growth of the InGaN materials. When the green light multiple quantum well layer is growing, a thickness of a barrier layer of the green light multiple quantum well is set to be 5-25 nm, an In content is in the range of 20%-85%, a thickness of a well layer is 1-7 nm, and a target band is locked at 515-550 nm; when the blue light multiple quantum well layer is growing, a thickness of a barrier layer of the blue light multiple quantum well is set to be 5-25 nm, an In content is in the range of 10%-40%, a thickness of a well layer is 1-7 nm, and a target band is locked at 440-470 nm.
S6: Adjusting the temperature of the reaction chamber to 900-1100° C. to grow a P-type GaN layer, wherein within this temperature range, a P-type GaN layer with a thickness of about 50-250 nm is grown by adding magnesium (Mg) as a doping element, and the doping concentration of the magnesium (Mg) is >1×10¹⁸/cm³ to ensure effective hole injection.
S7: Reducing the temperature below 800° C. for for annealing process to release stress, thus to stabilize the bonding structure and enhance device performance and reliability.
S8: Completing the electrical connections and cutting into single chips ready for packaging and final testing.

The implementation method of the Embodiment 2 is as follows.

The difference between Embodiment 2 and Embodiment 1 is that the type of the LED chip 5 is a flip chip. The electrodes of the LED chip 5 are toward the bracket 1, a side of the LED chip 5 in contact with the bracket 1 is coated with a die bonding glue 6, and the die bonding glue 6 is a solder paste. The LED chip 5 is fixedly connected and electrically connected to the bracket 1 through the solder paste. The material of the substrate 51 is sapphire. The sapphire substrate has extremely high chemical stability and thermal stability, which is suitable for the high temperature environment during the LED growth.

The implementation method of Embodiment 3 is as follows.

The difference between Embodiment 3 and Embodiment 1 is that the total number of layers of the multiple quantum well layer 55 is 5-10 layers. By adjusting the total number of layers of the multiple quantum well layer 55, the light output intensity and spectral characteristics of the LED can be regulated. The range of 5-10 layers can ensure sufficient quantum wells, so as to improve the luminous efficiency, while avoiding the increase of complexity and the possible efficiency reduction caused by excessive stacking.

Increasing the number of the multiple quantum well layers to 5-10 layers means that more light-emitting units can contribute to the overall light output, providing the possibility of more fine tuning of the spectrum. More quantum well layers can increase the chances of generating the photons, thereby improving the luminous efficiency. More quantum well layers provide a wider modulation space, and the fine tuning of the spectrum can be achieved by adjusting the thickness of different layers, the material ratio, and the In content and so on, so as to achieve a wider color gamut and higher color saturation. The multiple quantum well layer 55 is in the range of 5-10 layers, aiming to ensure that the performance is improved without giving up the production efficiency or increasing the excessive complexity.

The implementation method of the Embodiment 4 is as follows.

The difference between the Embodiment 4 and the Embodiment 1 is that several blue light multiple quantum well layers 551 and several green light multiple quantum well layers 552 are stacked in groups, that is, all of the blue light multiple quantum well layers 551 are stacked first and then all of the green light multiple quantum wells 552 are stacked, or all of the green light multiple quantum well layers 552 are stacked first and then all of the blue light multiple quantum well layers 551 are stacked. The stacking in groups simplifies the manufacturing process steps, avoids the complex and precise control required in the process of alternating deposition of the quantum well layers of different wavelengths, and reduces the manufacturing difficulty and cost, so that the production efficiency is improved. Since the interface properties between the same quantum well layers are similar, the stacking in groups is beneficial to reduce the interface defects and to improve the internal consistency of the device, thereby improving the overall photoelectric conversion efficiency and reliability.

The implementation method of Embodiment 5 is as follows.

The difference between Embodiment 5 and Embodiment 1 is that the color of the phosphor 4 is yellow, and the yellow phosphor can interact with the directly emitted blue light and green light to supplement the yellow part of the light source, and can also indirectly synthesize white light with the blue light or richer intermediate colors with the green and blue lights, thereby improving the saturation and naturalness of the overall color.

In conclusion, when the LED lamp beads made of the package structure proposed in the present disclosure are electrified and emit light, the NTSC color gamut of the spectrum composed of the blue light of the chip, the green light of the chip, and the red phosphor can reach 100%-130%, which is 5%-65% higher than the color gamut of the blue light excitation phosphor, close to the color gamut of the RGB scheme of the pure chip. At the same time, the color gamut of the present disclosure is 5%-15% lower than the color gamut of the RGB scheme of the pure chip, but the cost can be reduced by 30%-60%. Besides, the color gamut of this scheme is equivalent to that of the BG chip matching with phosphor, however, due to fewer chips, the process time and production risks can be effectively reduced. The package structure, color gamut and life of this scheme can be closer to the RGB scheme of the pure chip, but the cost can be greatly reduced. Meanwhile, compared with the RGB scheme of the pure chip, the driving scheme of the application end of the package structure of this scheme will be simpler, and the electrical design scheme of the substrate will also be simpler, which will save the design costs, material production costs and improve the production yields. In addition, the color gamut of this scheme is equivalent to that of the BG chip matching with phosphor, however, due to fewer chips, the process time and production risks can be effectively reduced.

It should be understood that the terms “first”, “second”, etc. are used in the present disclosure to describe various information, but this information should not be limited to these terms. These terms are only used to distinguish the same types of information from each other. For example, without departing from the scope of the present disclosure, the “first” information may also be referred to as the “second” information, and similarly, the “second” information may also be referred to as the “first” information. In addition, the terms “center”, “upper”, “lower”, “left”, “right”, “vertical”, “horizontal”, “inside”, “outside”, etc. indicate the orientation or position relationship based on the orientation or position relationship shown in the accompanying drawings, which is only for the convenience of describing the present disclosure and simplifying the description, rather than indicating or implying that the device or element referred to must have a specific orientation, be constructed and operated in a specific orientation, and therefore cannot be understood as a limitation of the present disclosure.

The above is a preferred embodiment of the present disclosure. It should be noted that for ordinary technicians in the technical field, several improvements and modifications can be made without departing from the principles of the present disclosure, and these improvements and modifications are also considered to be within the scope of protection of the present disclosure.

What is claimed is:

1. A wide color gamut LED package structure, comprising a bracket, wherein a function of the bracket is to provide physical support and electrical connection for components mounted on the bracket; an LED chip is mounted on a top surface of the bracket, and the LED chip is one of a face up chip, a vertical chip and a flip chip; a packaging mechanism is sleeved on the LED chip and includes a packaging glue; the packaging glue is mixed with a phosphor, and the phosphor is red;
the LED chip comprises a multiple quantum well layer, the multiple quantum well layer is used to generate light of different wavelengths, and the multiple quantum well layer includes several blue light multiple quantum well layers and several green light multiple quantum well layers.

2. The wide color gamut LED package structure according to claim 1, wherein the blue light multiple quantum well layer and the green light multiple quantum well layer are both composed of an InGaN barrier layer and an InGaN well layer, the InGaN barrier layer of the green light multiple quantum well layer has a thickness of 5-25 nm with an In content of 20%-85%, and an emission wavelength of 515-550 nm; the InGaN well layer of the green light multiple quantum well layer has a thickness of 1-7 nm with and an In content of 1%-25%; the InGaN barrier layer of the blue light multiple quantum well layer has a thickness of 5-25 nm, with an In content of 10%-40%, and an emission wavelength of 440-470 nm; the InGaN well layer of the blue light multiple quantum well layer has a thickness of 1-7 nm, with and an In content of 1%-25%.

3. The wide color gamut LED package structure according to claim 1, wherein a P-type GaN layer is arranged above the multiple quantum well layer, and an N-type GaN layer is arranged below the multiple quantum well layer; the N-type GaN layer is used to provide electrons, the P-type GaN layer is used to provide holes, and the P-type GaN layer and the N-type GaN layer form a P-N junction together.

4. The wide color gamut LED package structure according to claim 3, wherein an undoped GaN layer is configured below the N-type GaN layer, the LED chip comprises a substrate, and a GaN buffer layer is configured between the undoped GaN layer and the substrate.

5. The wide color gamut LED package structure according to claim 1, wherein the packaging mechanism comprises a bracket cup that is made of a transparent or opaque material, the bracket cup is fixedly connected to the bracket, and is sleeved outside the packaging glue.

6. The wide color gamut LED package structure according to claim 1, wherein positive electrode and negative electrodes of the LED chip are both welded with bonding wires, an end of the bonding wire is fixedly connected to the bracket, and the bracket is electrically connected to the LED chip through the bonding wire.

7. The wide color gamut LED package structure according to claim 1, wherein a side of the LED chip in contact with the bracket is coated with a die bonding glue, and the LED chip is fixedly connected to the bracket through the die bonding glue.

8. The wide color gamut LED package structure according to claim 1, wherein a plurality of the blue light multiple quantum well layers and a plurality of the green light multiple quantum well layers are alternately stacked.

9. A production method for the wide color gamut LED package structure according to claim 1, comprising the following Steps:
Step 1: growing an epitaxial layer, wherein a metal-organic chemical vapor deposition (MOCVD) is used to grow the epitaxial layer for an LED chip;
Step 2: fabricating the LED chip, wherein electrodes, current expansion layers, current blocking layers, protective layers, reflective layers, etc. are made on the chips, and finally single LED chips are obtained after cutting;
Step 3: die bonding, wherein the LED chip is fixed on a bracket;
Step 4: bonding wire, wherein the bracket is electrically connected to the chip through a bonding wire;
Step 5: setting a fluorescent glue, wherein the phosphor glue is set on a side of a functional area of the bracket by means of dispensing or spraying; preferably, the phosphor in the fluorescent glue is a red fluoride phosphor; and
Step 6: testing and packaging.

10. The production method of the wide color gamut LED package structure according to claim 1, wherein the step 1 further comprises the following steps:
adjusting a temperature of a reaction chamber to the range of 650-950° C. to lay a foundation for a high-quality growth of InGaN materials; when the green light multiple quantum well layer is growing, a thickness of a green multiple quantum well barrier layer of is set to be 5-25 nm, with an In content is in the range of 20%-85%, a thickness of a well layer is 1-7 nm, and a target band is locked at 515-550 nm; when the blue light multiple quantum well layer is growing, a thickness of a blue light multiple quantum well barrier layer is set to be 5-25 nm with an In content is in the range of 10%-40%, a thickness of a well layer is 1-7 nm, and a target band is locked at 440-470 nm.
